(19) United States
(12) Patent Application Publication
(10) Pub. No.: US 2016/0029486 A1
(43) Pub. Date: Jan. 28, 2016

(54) SOLDER JOINT STRUCTURE AND ELECTRONIC COMPONENT MODULE INCLUDING THE SAME

(71) Applicant: SAMSUNG ELECTRO-MECHANICS CO., LTD., Suwon-Si (KR)

(72) Inventors: Young Ho JEON, Suwon-Si (KR); Thomas A. Kim, Suwon-Si (KR); Kyung In Kang, Suwon-Si (KR); Seung Yong Choi, Suwon-Si (KR); Ki Chan Kim, Suwon-Si (KR)

(73) Assignee: SAMSUNG ELECTRO-MECHANICS CO., LTD., Suwon-Si (KR)

(21) Appl. No.: 14/617,898

(22) Filed: Feb. 9, 2015

(30) Foreign Application Priority Data
Jul. 24, 2014 (KR) 10-2014-0094124

(51) Int. Cl. H05K 1/11; H05K 1/18; H05K 1/03; H05K 1/02; H05K 1/09

(52) U.S. Cl. CPC H05K 1/111; H05K 1/0298; H05K 1/09; H05K 1/0353; H05K 1/181; H05K 2201/1075

(57) ABSTRACT

A solder joint structure may include a first active surface on which a plurality of connection terminals are provided, a second active surface on which a plurality of bonding pads are provided, and a plurality of solder bonding portions bonded to the connection terminals and the bonding pads. A bonding area between the connection terminal and the solder bonding portion may be smaller than a bonding area between the bonding pad and the solder bonding portion.

### CROSS-REFERENCE TO RELATED APPLICATION

This application claims the priority and benefit of Korean Patent Application No. 10-2014-0094124, filed on Jul. 24, 2014, with the Korean Intellectual Property Office, the disclosure of which is incorporated herein by reference.

### BACKGROUND

Some embodiments of present disclosure may relate to a solder joint structure capable of reducing crack occurrence or detachment in a solder bonding portion, and an electronic component module including the same.

Semiconductor chip packages or electronic component modules commonly use solder balls or solder bumps in order to make electrical connections with a semiconductor chip, an electronic component, and are mounted on a circuit board.

The above-mentioned method may be suitable for subminiature semiconductor chip packages which are relatively small and lightweight and have improved performance, since it can be easily applied to small semiconductor chips, as compared to a wire bonding method, and increase the number of possible input and output terminals.

However, due to a difference in coefficients of thermal expansion between a semiconductor chip and a circuit board, and the like, cracking may occur in bonding portions of solder balls.

### RELATED ART DOCUMENT

(Patent Document 1) Korean Patent Laid-Open Publication No. 10-2003-0053159

### SUMMARY

Some embodiments of the present disclosure may provide a solder joint structure capable of reducing crack occurrence or detachment in a solder bonding portion, and an electronic component module including the same.

According to an aspect of the present disclosure, a solder joint structure may include: a first active surface on which a plurality of connection terminals are provided; a second active surface on which a plurality of bonding pads are provided; and a plurality of solder bonding portions bonded to/between the connection terminals and the bonding pads. A bonding area between the connection terminal and the solder bonding portion may be smaller than a bonding area between the bonding pad and the solder bonding portion.

According to another aspect of the present disclosure, an electronic component module may include: at least one electronic component provided with a plurality of connection terminals; a circuit board provided with a plurality of bonding pads, the bonding pads being smaller than the connection terminals; solder bonding portions bonded to/between the connection terminals and the bonding pads to form connections therebetween; and a molded portion enclosing the solder bonding portions and filling a space between the electronic component and the circuit board.

According to another aspect of the present disclosure, an electronic component module may include: at least one electronic component provided with a plurality of connection terminals; a circuit board provided with a plurality of bonding pads; and solder balls bonded to/between the connection terminals and the bonding pads to form electrical connections therebetween. A bonding area between the connection terminal and the solder ball may be different from a bonding area between the bonding pad and the solder ball.

### BRIEF DESCRIPTION OF THE DRAWINGS

The above and other aspects, features and advantages of the present disclosure will be more clearly understood from the following detailed description taken in conjunction with the accompanying drawings, in which:

FIG. 1 is a cross-sectional view schematically illustrating an electronic component module including a solder joint structure using solder balls according to an exemplary embodiment in the present disclosure; and

FIG. 2 is a table schematically illustrating bonding pads of circuit boards and insulating protective layers prepared for a test according to exemplary embodiments in the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

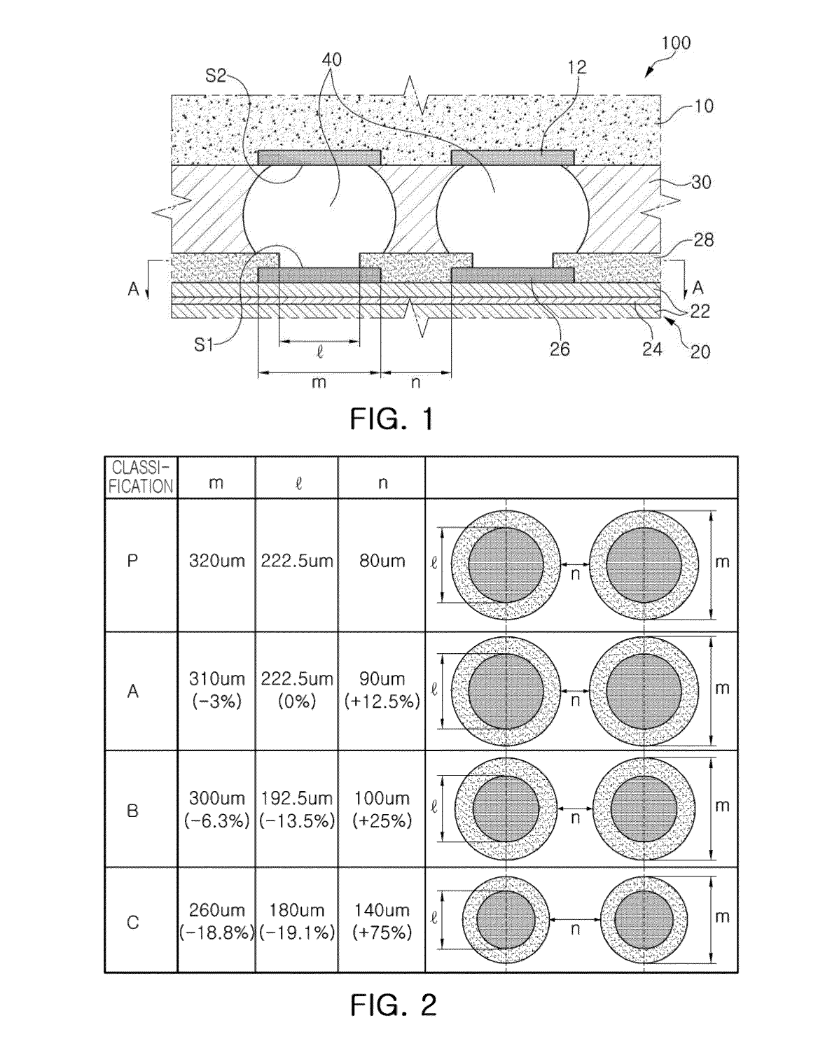

FIG. 1 is a cross-sectional view schematically illustrating an electronic component module including a solder joint structure using solder balls according to an exemplary embodiment in the present disclosure.

Referring to FIG. 1, an electronic component module 100 according to the present exemplary embodiment may include an electronic component 10 and a circuit board 20. The electronic component 10 may be provided with a plurality of connection terminals 12. The circuit board 20 may be provided with a plurality of bonding pads 26. The circuit board 20 and the electronic component 10 may be electrically connected by solder bonding portions 40.

For example, the electronic component 10 may be a semiconductor chip, but is not limited thereto. The electronic component 10 may include various electronic components such as passive elements.

The electronic component 10 may be formed of, for example, but not limited to, ceramic, or the like. At least one connection terminal 12 may be formed on an active surface (e.g., a lower surface) of the electronic component 10, for example, in the groove of the electronic component 10. Here, the connection terminal 12 may be a portion of a metal wiring formed on the lower surface of the electronic component 10 and may be provided in a pad form. Here, the active surface may refer to a surface of the electronic component 10 on which the connection terminal 12 or an metal wiring is formed.

The electronic component 10 may be mounted on or over the circuit board 20 through a flip chip bonding scheme by using the solder bonding portions 40, or the like.

The circuit board 20 may be a single layer board or a multilayer board. The plurality of bonding pads 26 may be formed on an active surface (e.g., an upper surface) of the circuit board 20 on which the electronic component 10 is to be mounted. Here, the active surface may refer to a surface of the circuit board 20 on which the bonding pads 26 are formed.

The circuit board 20 may have an insulator 22 of prepreg or the like and a wiring pattern 24 stacked therein. Portions of the wiring pattern 24 may be formed as the bonding pads 26 to be exposed to the outside of the circuit board 20. In this case, an insulating protective layer 28 may be formed on portions of the bonding pads 26, for example, but not limited to peripheral portions of the surface of the bonding pads 26. Therefore, an area of an actual exposed region of the bonding pad 26 may correspond to a size of an opening formed in the insulating protective layer 28.

For example, the bonding pads 26 may be formed of copper (Cu) and a surface thereof may be plated with gold (Au) in order to increase bonding reliability.

In addition, the insulating protective layer 28 may be formed of solder resist, but is not limited thereto.

The solder bonding portions 40 electrically may connect the connection terminals 12 of the electronic component 10 to the bonding pads 26 of the circuit board 20. The number of solder bonding portions 40 may correspond to the number of connection terminals 12 of the electronic component 10 or the number of bonding pads 26 of the circuit board 20. Alternatively, the solder bonding portions 40 maybe selectively and partially provided, if necessary.

The solder bonding portions 40 may be formed of a conductive material and/or has a shape capable of electrically connecting the connection terminals 12 of the electronic component 10 to the bonding pads 26 of the circuit board 20. The solder bonding portions 40 according to the present exemplary embodiment may be solder balls, but are not limited thereto. The solder bonding portions 40 may be variously changed. For example, solder bumps may be used therefor.

In addition, a molded portion 30 may be formed between the electronic component 10 and the circuit board 20. The molded portion 30 may fill a space between the electronic component 10 and the circuit board 20. Therefore, the solder balls 40 may connect the electronic component 10 to the circuit board 20 while being buried in the molded portion 30.

The molded portion 30 may be formed of an insulating material such as epoxy. For example, an epoxy molding compound (EMC) may be used.

The molded portion 30 may be formed by using an underfill process, or the like, but is not limited thereto.

In case of the electronic component module 100 configured as described above, heat may be continuously applied thereto during a manufacturing process or an operating process of the electronic component 10. However, the electronic component module 100 may include a plurality of different materials which are bonded to each other, and coefficients of thermal expansion (CTE) of these materials may be different from each other.

Therefore, as thermal expansion and contraction are repeated, cracks may occur in the bonding portions of the solder balls 40 or detachment may occur in the insulating protective layer 28, and thus solder may be introduced into the electronic component module 100.

In the case in which heat is applied to the electronic component module 100 according to the present exemplary embodiment, the CTE of the solder balls 40 and the molded portion 30 (e.g., EMC) may be changed to about 21.6 ppm/° C. and about 35 ppm/° C., respectively, while the CTE of the circuit board 20 may be slightly changed to about 10 ppm/° C.

This is because the CTE of the insulating protective layer 28 (e.g., solder resist) of the circuit board 20 is lower than that of the solder balls 40 or the molded portion 30 (e.g., EMC).

By the above-mentioned thermal deformation, the surface (e.g., the insulating protective layer) of the circuit board 20 between the solder balls 40 and the molded portion 30 may be locally subjected to large stress, whereby the insulating protective layer 28 may be detached from the circuit board 20 or the cracks may occur in the bonding portions between the solder balls 40 and the bonding pads 26.

The space between the solder balls 40 may be reduced. However, as an interval between the solder balls 40 is reduced, the above-mentioned problems may be aggravated. The interval between the solder balls 40 may be increased. In order to increase the interval between the solder balls 40, the connection terminals 12 of the electronic component 10 may need to be further spaced apart from each other. This may result in an increase in the size of the electronic component 10. However, the above-mentioned problems may be dealt with while the interval between the solder balls 40 is maintained.

In order to solve the above-mentioned problems, a test was performed by adjusting or changing the areas of bonding surfaces S1 and S2 of the bonding pad 26 and the connection terminal 12, respectively, and it can be seen that cracking or the detachment of the insulating protective layer 28 frequently occurred in a case in which the areas of the bonding surfaces S1 and S2 of the bonding pad 26 and the connection terminal 12 bonded to the solder ball 40 were the same as each other. Here, the bonding surfaces S1 and S2 refer to respective areas of the connection terminal 12 and the bonding pad 26 directly bonded to the solder ball 40, in which each area is defined by a portion of the connection terminal 12 or the bonding pad 26 exposed through the opening of the insulating protective layer 28, or the like.

FIG. 2 is a table schematically illustrating cross-sections of bonding pads and an insulating protective layer of circuit boards, taken along line A-A of FIG. 1, prepared for performing the test according to the present exemplary embodiment. FIG. 2 shows the bonding pad 26 of the circuit board 20 and the bonding surface S1 with various diameters, and the degree of cracking or detachment was measured. In addition, in the present test, a diameter of the bonding surface S2 of the connection terminal 12 of the electronic component 10 was set to 220 μm.

Referring to FIG. 2, in a P board, the diameter m of the bonding pad 26 was set to 320 μm, the diameter l of the bonding surface S1 (the diameter of the opening of the insulating protective layer 28) was set to 222.5 μm, and a distance n between the bonding pads 26 was set to 80 μm. Therefore, the P board refers to an exemplary embodiment of the circuit board 20 in which the diameter l of the bonding surface S1 of the bonding pad 26 is the same as that of the bonding surface S2 of the connection terminal 12.

In an A board, the diameter m of the bonding pad 26 was set to 310 μm, the diameter l of the bonding surface S1 (the diameter of the opening of the insulating protective layer 28) was set to 222.5 μm, and the distance n between the bonding pads 26 was set to 90 μm. Therefore, the A board refers to another exemplary embodiment of the circuit board 20 in which the diameter l of the bonding surface S1 is the same as that of the bonding surface of the P board, while the distance n between the bonding pads 26 is increased by reducing the diameter m of the bonding pad 26.

In a B board, the diameter m of the bonding pad 26 was set to 300 μm and the diameter l of the bonding surface S1 was set to 192.5 μm. The distance n between the bonding pads 26 was set to 100 μm. Therefore, the B board refers to another exemplary embodiment of the circuit board 20 in which both the diameter l of the bonding surface S1 and the diameter m of the bonding pad 26 are reduced as compared to the P board.

In the B board, the diameter m of the bonding pad 26 was reduced by about 6.3% as compared to the P board, and the diameter l of the bonding surface S1 was reduced by about 13.5% as compared to the P board. In addition, the distance n between the bonding pads 26 of the B board was increased by about 25% as compared to the P board.

In a C board, the diameter m of the bonding pad 26 was set to 260 μm, and the diameter l of the bonding surface S1 was set to 180 μm. The distance n between the bonding pads 26 was set to 140 μm. Therefore, the C board refers to another exemplary embodiment of the circuit board 20 in which both the diameter l of the bonding surface S1 and the diameter m of the bonding pad 26 are reduced as compared to the B board.

In the C board, the diameter m of the bonding pad 26 was reduced by about 18.8% as compared to the P board, and the diameter l of the bonding surface S1 was reduced by about 19.1% as compared to the P board. In addition, the distance n between the bonding pads 26 of the C board was increased by about 75% as compared to the P board.

The results obtained by forming respective solder joint structures using the aforementioned exemplary embodiments of circuit boards 20, applying heat thereto to perform a temperature test are listed in the following Table 1:

TABLE 1

| | Number of | Product | Defective Product |
|---|---|---|---|
| | Test | with Good | (Occurrence of |
| Classification | Samples | Results | Cracking/Detachment) |
| P | 1607 | 1606 | 7 |
| A | 1607 | 1606 | 1 |
| B | 1583 | 1583 | — |
| C | 1561 | 1561 | — |

Referring to Table 1, as a result of performing the test with respect to about 1600 samples of respective P, A, B and C boards, defects occurred in seven P board samples; defects occurred in one A board sample; and no defects occurred in B and C board samples.

Therefore, it can be seen that the defect rate resulting from the cracking or the detachment may be reduced in the case of using the B board or the C board in which the diameter l of the bonding surface S1 is reduced as compared to the P board and the distance n between the bonding pads 26 is increased by reducing the diameter m of the bonding pad 26 as compared to the P board.

In addition, based on the test results, it can be seen that as the interval between adjacent solder balls 40 is reduced as in the P board, stress may be concentrated on the solder balls 40 or the insulating protective layer 28, resulting in cracking or detachment.

On the other hand, it can be seen that in a case in which the diameter l of the bonding surface S1 of the bonding pad 26 bonded to the solder ball 40 is reduced in a stress concentration zone surrounded by the electronic component 10, the solder ball 40, the molded portion 30, and the circuit board 20, as in the B board or the C board, the interval between adjacent solder balls 40 may be secured, cracking in the solder balls 40 or the detachment of the insulating protective layer 28 may be reduced.

Meanwhile, even when the bonding area of the solder ball 40 of the C board was reduced by about 20% as compared to the P board, bonding reliability was not problematic. The reason is that the molded portion 30 surrounding the solder balls 40 may serve as a buffer against, for example, but not limited to, thermal and physical impacts.

Therefore, the solder joint structure according to the some present exemplary embodiments may have the above-mentioned exemplary effects in the case in which the bonding surface S1 of the bonding pad 26 of the circuit board 20 is formed to be 80% to 100% of the bonding surface S2 of the connection terminal 12 of the electronic component 10.

Meanwhile, the solder joint structure and the electronic component module having the same according to the above-described exemplary embodiments may be variously modified. For example, the electronic component module 100 in which the electronic component 10 is mounted on the circuit board 20 has been described by way of example. However, the present inventive concept is not limited thereto, and may be variously applied as long as a structure has elements bonded to each other through solder balls as in a case in which a circuit board is mounted on another circuit board, or the like.

As set forth above, in the solder joint structure and the electronic component module according to some exemplary embodiments of the present disclosure, the diameter of the bonding surface of the circuit board 20 bonded to the solder ball 40 may be set to be smaller than that of the bonding surface of the connection terminal 12 of the electronic component 10 bonded to the solder ball, and/or an interval between adjacent solder balls 26 may be increased by reducing the diameter of the bonding pad of the circuit board, and the occurrence of cracking or detachment may be reduced.

While exemplary embodiments have been shown and described above, it will be apparent to those skilled in the art that modifications and variations could be made without departing from the scope of the present invention as defined by the appended claims.

What is claimed is:

1. An electronic component module, comprising:
at least one electronic component provided with a plurality of connection terminals;
a circuit board provided with a plurality of bonding pads; and
solder balls bonded between the connection terminals and the bonding pads to form electrical connections therebetween,
wherein a bonding area between the connection terminal and the solder ball is different from a bonding area between the bonding pad and the solder ball.

2. The electronic component module of claim 1, wherein the bonding area between the bonding pad and the solder ball is smaller than the bonding area between the connection terminal and the solder ball.

3. The electronic component module of claim 2, wherein the bonding area between the bonding pad and the solder ball is 80% to 100% of the bonding area between the connection terminal and the solder ball.

4. The electronic component module of claim 1, wherein the circuit board includes:
an insulator;
a wiring pattern disposed on the insulator; and
an insulating protective layer disposed on the wiring pattern, and
wherein the bonding pad is formed of a portion of the wiring pattern.

5. The electronic component module of claim 4, wherein a portion of the bonding pad of the circuit board exposed through an opening provided in the insulating protective layer is bonded to the solder ball.

6. The electronic component module of claim 5, wherein the insulating protective layer is formed of solder resist.

7. The electronic component module of claim 6, wherein the bonding pad is formed of a copper (Cu) material.

8. The electronic component module of claim 1, further comprising a molded portion filling a space between the electronic component and the circuit board.

9. The electronic component module of claim 8, wherein the molded portion is formed of an epoxy molding compound (EMC).

10. An electronic component module, comprising:
an electronic component provided with a plurality of connection terminals;
a circuit board provided with a plurality of bonding pads, the bonding pads being smaller than the connection terminals;
solder bonding portions bonded between the connection terminals and the bonding pads to form connections therebetween; and
a molded portion enclosing the solder bonding portions and filling a space between the electronic component and the circuit board.

11. The electronic component module of claim 10, wherein the connection terminals and the bonding pads are disposed to face each other.

12. A solder joint structure, comprising:
a first active surface on which a plurality of connection terminals are provided;
a second active surface on which a plurality of bonding pads are provided; and
at least one solder bonding portion bonded between the connection terminals and the bonding pads,
wherein a bonding area between the connection terminal and the solder bonding portion is smaller than a bonding area between the bonding pad and the solder bonding portion.

13. The solder joint structure of claim 12, wherein:
the first active surface is an active surface of an electronic component, and
the second active surface is an active surface of a circuit board.

14. The solder joint structure of claim 12, further comprising a molded portion filling a space between the first active surface and the second active surface.
